(19) United States
(12) Patent Application Publication
(10) Pub. No.: US 2007/0114577 A1
(43) Pub. Date: May 24, 2007

(54) SEMICONDUCTOR DEVICE

(75) Inventor: Atsushi NARAZAKI, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 11/427,608

(22) Filed: Jun. 29, 2006

(30) Foreign Application Priority Data
Nov. 18, 2005 (JP) 2005-333656

(51) Int. Cl. H01L 29/80

(52) U.S. Cl. 257/273

(57) ABSTRACT

One of the aspects of the present invention is to provide a semiconductor device, which includes a semiconductor substrate, a surface electrode on the semiconductor substrate, and a gate wiring on the semiconductor substrate, the gate wiring being spaced from the surface electrode. It also includes a metal layer on the surface electrode, a lead terminal plate connected onto the metal layer, and a polyimide layer covering the gate wiring.

### BACKGROUND OF THE INVENTION

1) Technical field of the Invention

The present invention relates to a semiconductor device, and in particular, relates to so-called a direct-lead-bonding type semiconductor device having a lead plate for directly connecting a surface electrode of the semiconductor chip with a terminal.

2) Description of Related Arts

The recent power semiconductor device such as a power MOSFET (Metal Oxide Semiconductor Field Effect Transistor) and an IGBT (Insulated Gate Bipolar Transistor) utilizes a direct lead plate, instead of a bonding wire, for connecting an emitter electrode with a lead terminal.

FIG. 19 is a top plan view of a semiconductor device having a conventional structure, which is entirely denoted by reference numeral 800, and FIG. 20 is a cross sectional view taken along a XIV-XIV line of FIG. 19. At the right half portion of FIG. 20, illustration of a polyimide layer 13 is eliminated for better understanding.

As shown in FIGS. 19 and 20, the semiconductor device 800 includes a semiconductor chip 1 such as the IGBT. The semiconductor chip 1 includes an emitter electrode 2 and a gate wiring 4 formed on the top surface, with the gate wiring connected to a gate electrode 3. An overcoat layer 5 is formed on the emitter electrode 2 and the peripheral region of the gate electrode 3, covering the top surface of the semiconductor chip 1. Further provided on the emitter electrode 2 is a metal layer 6, on which a lead terminal plate 10 is connected via a solder layer 11. It should be noted that the metal layer 6, the lead terminal plate 10, and the solder layer 11 are not shown in FIG. 19.

Moreover, the semiconductor chip 1 includes a collector electrode 7 on the bottom surface. The semiconductor chip 1 is bonded via a solder layer 8 on the substrate 9 having a patterned wiring (not shown) on the top thereof.

FIG. 21 is a top plan view of the conventional semiconductor device 800 with the metal layer 6 formed thereon, and FIG. 22 is a cross sectional view taken along a XXI-XXI line of FIG. 21. It should be noted that the lead terminal plate 10 and the solder layer 11 are not shown in FIG. 21. Reference numerals in FIGS. 21, 22 similar to those in FIGS. 19 and 20 denote the same or similar components. FIGS. 21 and 22 illustrate the semiconductor device having the metal 6, the lead terminal plate 10, and the solder layer 11 which are precisely aligned to the emitter electrode 2.

In more particular, formed on the semiconductor substrate 1 is a polycrystalline silicon wiring 21 via an underlaid oxide layer 20, on which the gate wiring 4 is formed, as illustrated in FIG. 22. Also, an inter-layer insulating layer 22 is formed between the emitter electrode 2 and the gate wiring 4. See, for example, a Japanese laid-open patent publication application No. 4-133474, A.

In the manufacturing process of the semiconductor device 800, the metal layer 6 may sometimes be formed offset relative to the emitter electrode 2. FIG. 23 illustrates a top plan view where the metal layer 6 is formed offset to the left, and FIG. 24 is a cross sectional view taken along a XXIII-XXIII line of FIG. 23, with the solder layer 11 and the lead terminal plate 10 eliminated. Reference numerals in FIGS. 23 and 24 similar to those in FIGS. 19 and 20 denote the same or similar components.

In the semiconductor device 810 shown in FIG. 24, when the metal layer 6 is formed offset and above the gate wiring 4, stress and heat is applied to the gate wiring 4 during a step for connecting the lead terminal plate 10 via the solder layer 11 with the metal layer 6, thereby damaging the gate wiring 4. Even when the breakage of the gate wiring is not found in the manufacturing process, such stress and heat on the gate wiring may cause a problem of failure detected after shipping, thereby reducing reliability of the semiconductor device.

The present invention is made for addressing the problem and is to provide the direct-lead-bonding type semiconductor device, preventing the gate wiring from being damaged, even where the metal layer is formed offset and over the gate wiring.

### SUMMARY OF THE INVENTION

Further scope of applicability of the present invention will become apparent from the detailed description given hereinafter. However, it should be understood that the detailed description and specific examples, while indicating preferred embodiments of the invention, are given by way of illustration only, since various changes and modifications within the sprit and scope of the invention will become apparent to those skilled in the art from this detailed description.

According to one of the aspects of the present invention, a semiconductor device, which includes a semiconductor substrate, a surface electrode on the semiconductor substrate, and a gate wiring on the semiconductor substrate, the gate wiring being spaced from the surface electrode. It also includes a metal layer on the surface electrode, a lead terminal plate connected onto the metal layer, and a polyimide layer covering the gate wiring.

### BRIEF DESCRIPTION OF THE DRAWINGS

The present invention will more fully be understood from the detailed description given hereinafter and accompanying drawings which are given by way of illustration only, and thus are not limitative of the present invention.

FIG. 1 is a top plan view of the first embodiment of a semiconductor device according to the present invention.

FIG. 2 is a cross sectional view of the first embodiment of the semiconductor device according to the present invention.

FIG. 3 is a top plan view of the first embodiment of the semiconductor device according to the present invention.

FIG. 4 is a top plan view of the first embodiment of the semiconductor device according to the present invention.

FIG. 5 is a cross sectional view of the first embodiment of the semiconductor device according to the present invention.

FIG. 6 is a top plan view of the first embodiment of another semiconductor device according to the present invention.

FIG. 7 is a cross sectional view of the first embodiment of another semiconductor device according to the present invention.

FIG. 8 is a top plan view of the second embodiment of a semiconductor device according to the present invention.

FIG. 9 is a cross sectional view of the second embodiment of the semiconductor device according to the present invention.

FIG. 10 is a cross sectional view of the second embodiment of the semiconductor device according to the present invention.

FIG. 11 is a cross sectional view of the third embodiment of the semiconductor device according to the present invention.

FIG. 12 is a top plan view of the fourth embodiment of a semiconductor device according to the present invention.

FIG. 13 is a cross sectional view of the fourth embodiment of the semiconductor device according to the present invention.

FIG. 14 is a top plan view of the fifth embodiment of a semiconductor device according to the present invention.

FIG. 15 is a top plan view of the fifth embodiment of a semiconductor device according to the present invention.

FIG. 16 is a top plan view of the fifth embodiment of a semiconductor device according to the present invention.

FIG. 17 is a cross sectional view of the fifth embodiment of the semiconductor device according to the present invention.

FIG. 18 is a top plan view of the fifth embodiment of a semiconductor device according to the present invention.

FIG. 19 is a top plan view of a conventional semiconductor device.

FIG. 20 is a cross sectional view of the conventional semiconductor device.

FIG. 21 is a top plan view of a conventional semiconductor device.

FIG. 22 is a cross sectional view of the conventional semiconductor device.

FIG. 23 is a top plan view of a conventional semiconductor device.

FIG. 24 is a cross sectional view of the conventional semiconductor device.

### DETAILED DESCRIPTION OF THE PREFERRED EMBODIMENTS

### Embodiment 1

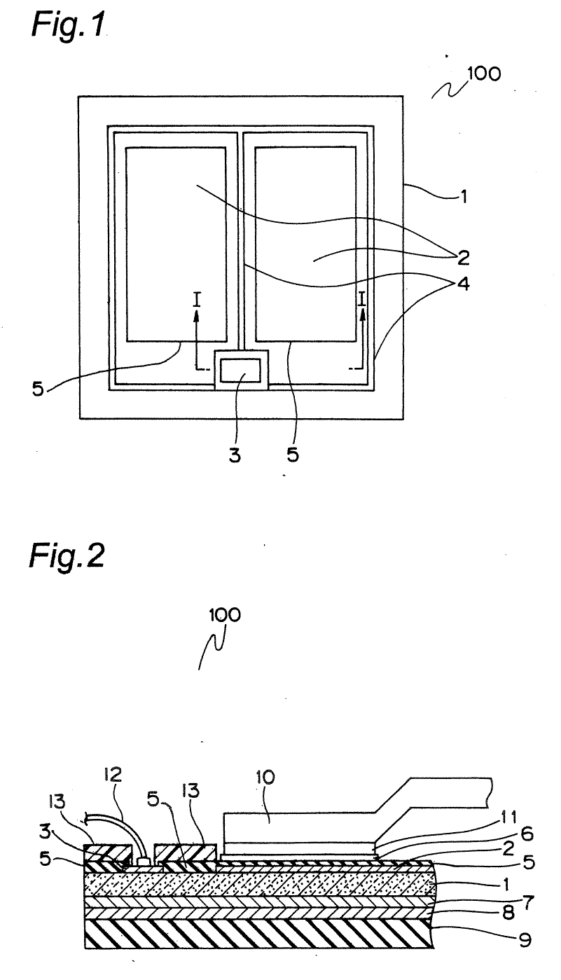

FIG. 1 is a top plan view of a first embodiment of a direct-lead-bonding type semiconductor device according to the present invention, before a polyimide layer is formed. FIG. 2 is a cross sectional view taken along a I-I line of FIG. 1, with the polyimide layer 13 eliminated at the right half portion thereof for better understanding.

The semiconductor device 100 includes a semiconductor chip 1 such as an IGBT. The semiconductor chip 1 has an emitter electrode (surface electrode) 2 and a gate electrode 3 formed on the top surface thereof. Those electrodes are made of metal such as aluminum. Connected with the gate electrode 3 is a gate wiring 4 of metal such as aluminum. Also, bonded on the gate electrode 3 is a bonding wire 12 of metal such as aluminum.

An overcoat layer 5 of material such as silicon dioxide and silicon nitride is formed on the emitter electrode 2 and the peripheral region of the gate electrode 3, covering the top surface of the semiconductor chip 1.

Further formed on the emitter electrode 2 is a metal layer 6 having a multilayer structure such as a Ti/Ni/Au-layer structure. A metal deposition process may be used to selectively form the metal layer 6 on the emitter electrode 2, by covering a metal mask on the top surface of the wafer (semiconductor chip 1) and depositing the respective metal on the emitter electrode. In the multilayer structure of the metal layer 6, the Ti-, Ni- and Au-layers perform functions serving as an agent for improving the ohmic contact with the emitter electrode 2, an adhesive agent with the solder layer 11, and an antioxidant agent of the Ni-layer, respectively. Besides of the Ti/Ni/Au-layer structure, the metal layer 6 may have another multilayer structure such as Al/Mo/Ni/Au-layer structure and Al/Ti/Ni/Au-layer structure. Also, the metal layer 6 may be formed by a sputtering process as well. Further, although not specifically indicated in the following embodiments, the sputtering process may also be used for forming the metal layer 6.

The direct-lead-bonding type semiconductor device 100 includes a lead terminal plate 10 bonded on the metal layer 6 via the solder layer 11 of metal such as Ag—Sn alloy. The lead terminal plate 10 may be formed of metal such as copper, for connecting with an external device (not shown).

Moreover, the semiconductor chip 1 includes a collector electrode (reverse electrode) 7 on the bottom surface, which has a multilayer structure such as an Al/Mo/Ni/Au-layer structure. Also, the semiconductor chip 1 is bonded through a solder layer 8 on the substrate 9 having a patterned wire (not shown) on the top thereof. The substrate 9 is made of insulating material such as alumina.

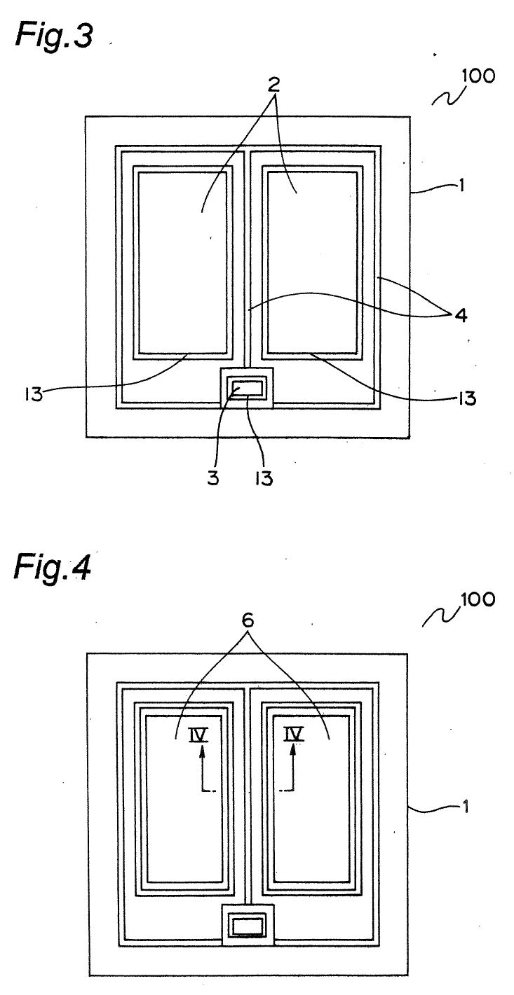

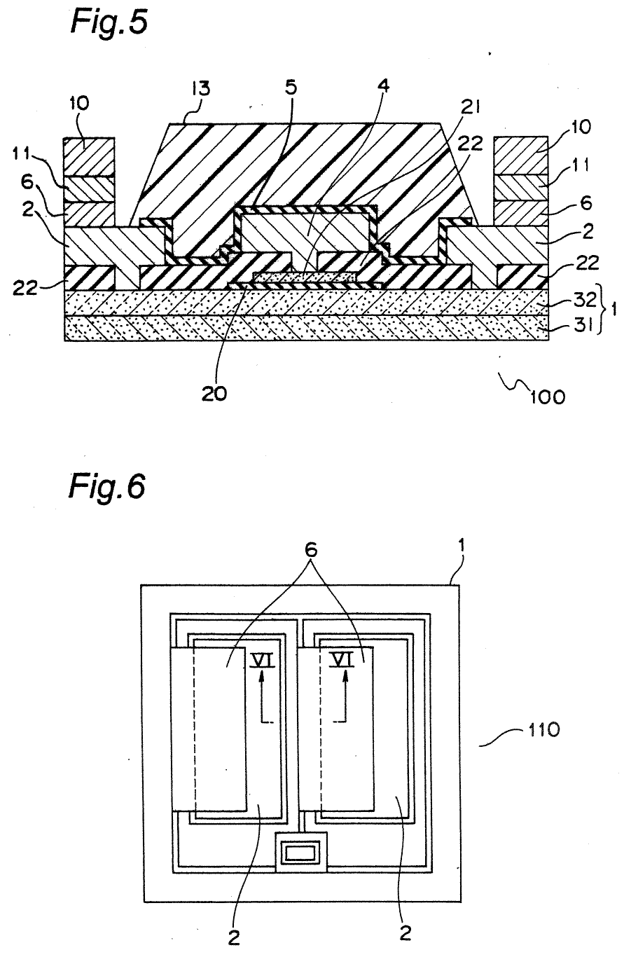

FIG. 3 is a top plan view of the semiconductor device after the polyimide layer 13 is formed, and FIG. 4 is another top plan view thereof after the metal layer 6 is further formed thereon. FIG. 5 is a cross sectional view taken along a IV-IV line of FIG. 4. A lead terminal plate 10 is bonded via the solder layer 11 on the metal layer 6.

In more particular, formed on the semiconductor chip 1 is a polycrystalline silicon wiring 21 via an underlaid oxide layer 20, on which the gate wiring 4 is formed, as illustrated in FIG. 5. Also, an inter-layer insulating layer 22 of material such as silicon dioxide is intervened between the emitter electrode 2 and the gate wiring 4. Further, the semiconductor chip includes an n-type epitaxial layer 31 and a p-type well region 32.

In the semiconductor device 100, an overcoat layer 5 is used to cover the gate wiring 4, on which the polyimide layer 13 is formed. The polyimide layer 13 preferably has thickness in the range between about 10 μm and about 50 μm, for instance.

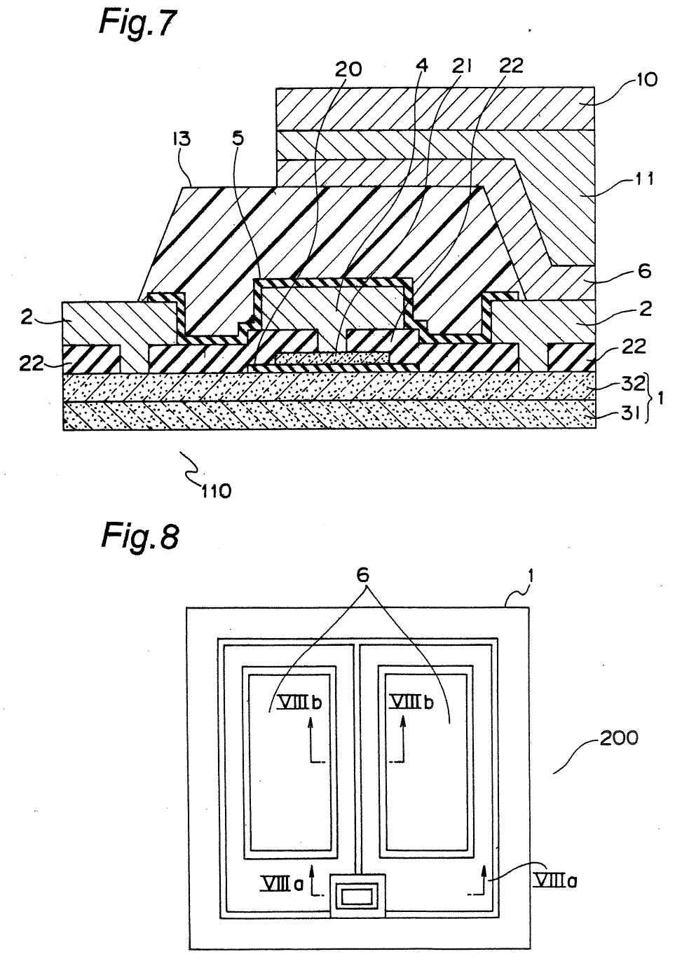

While FIGS. 3-5 illustrate the metal layer 6 that is precisely aligned against the emitter electrode 2, FIGS. 6-7 show the metal layer 6 formed offset (towards the left side in FIGS. 6 and 7) relative to the emitter electrode 2. Like this, even where the metal layer 6 is formed offset, the semiconductor device can be used as a non-defective product unless the device characteristic thereof is adversely affected.

FIG. 6 is a top plan view of the first embodiment of another semiconductor device according to the present invention, which is entirely denoted by reference numeral 110. Reference numerals in FIGS. 6 and 7 similar to those in FIGS. 1-5 denote the same or similar components.

In the manufacturing process of the semiconductor device 110, after depositing the gate wiring 4 and the emitter electrode 2, the overcoat layer 5 is formed and then the polyimide layer 13 is formed. The overcoat layer 5 and the polyimide layer 13 are formed by means of typical photolithography and etching.

In general, after forming the polyimide layer 13, the metal layer 6 is deposited with use of a metal mask. In the semiconductor device 110, the metal mask is arranged offset to the left towards the gate electrode 4 so that the metal layer 6 is formed over and extends beyond the polyimide layer 13. Therefore, the semiconductor device has the metal layer 6, the solder layer 11, and the lead terminal plate 10 laminating on the polyimide layer 13.

Thus, the semiconductor device 110 of the first embodiment of the present invention includes the polyimide layer 13 formed over and adjacent the gate wiring 4, so as to eliminate a stepped portion which is otherwise formed close to the gate wiring of the conventional semiconductor device as indicated by a mark “A” in FIG. 24. This reduces the stress and heat applied to the stepped portion even where the metal layer 6 is not precisely aligned and is formed adjacent the gate wiring 4, thereby avoiding the damage to the gate wiring 4.

In the above description with reference to FIG. 7, the metal layer 6, the solder layer 11 and the lead terminal plate 10 are offset formed over and extending beyond the gate electrode 4. Also in case that the offsetting degree is not so substantial, i.e., the solder layer 11 and the lead terminal plate 10 are offset formed, but not extending beyond the gate electrode 4, the polyimide layer 13 also prevents the damage of the gate wiring 4.

### Embodiment 2

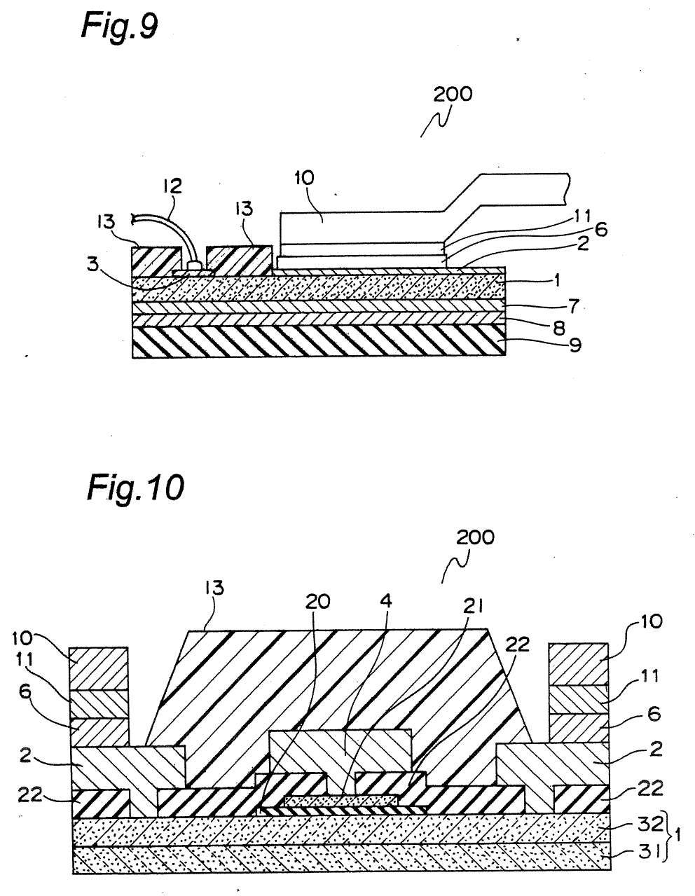

FIG. 8 is a top plan view of a second embodiment of a semiconductor device according to the present invention, and FIG. 9 is a cross sectional view taken along a VIIIa-VIIIa line of FIG. 8, with the polyimide layer 13 eliminated at the right half portion thereof. FIG. 10 is another cross sectional view taken along a VIIIb-VIIIb line of FIG. 8. Reference numerals in FIGS. 8-10 similar to those in FIGS. 1-5 denote the same or similar components.

The semiconductor device 200 according to the second embodiment of the present invention is has a structure similar to that of the semiconductor device 100 of the first embodiment except that the overcoat layer 5 is eliminated.

Another function of the polyimide layer 13 serving as a protection layer may eliminate the overcoat layer 5. This skips the production step of the overcoat layer 5, and simplifies the manufacturing process, thereby reducing the production cost.

### Embodiment 3

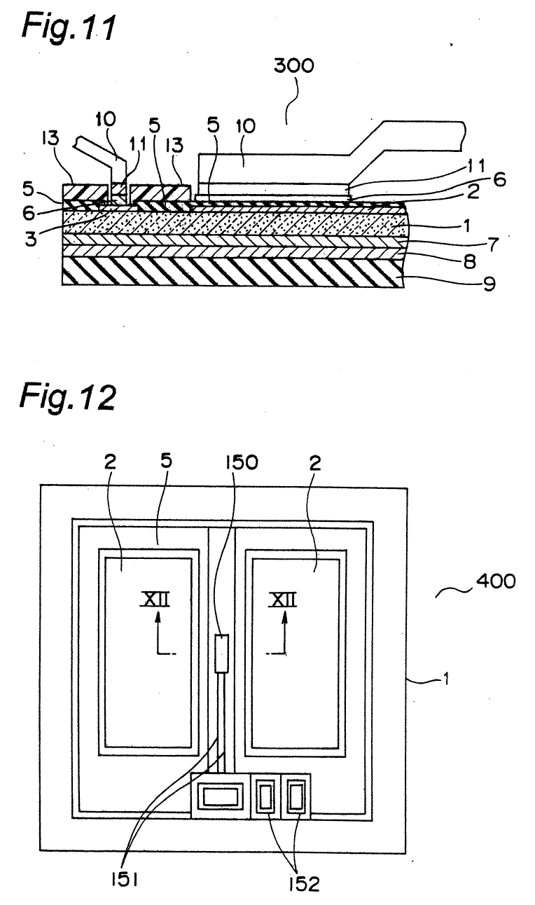

FIG. 11 is a cross sectional view of a third embodiment of a semiconductor device according to the present invention, which is entirely denoted by reference numeral 300. Reference numerals in FIG. 11 similar to those in FIG. 2 denote the same or similar components.

While the semiconductor device 100 includes a bonding wire 12 for connection with the gate electrode 3, the semiconductor device 300 includes a metal layer 6 deposited on the gate electrode 3, and a lead terminal plate 10 bonded on the gate electrode 3 via the solder layer 11.

The metal layer 6 on the gate electrode 3 may be deposited during the same production step as one on the emitter electrode 2, for example, by means of the deposition technique with the metal mask. The solder layer 11 for connection of the lead terminal onto the metal layer 6 over the gate electrode 3 may be made of Ag—Sn solder similar to one for connection of the lead terminal onto the metal layer 6 over the emitter electrode 2, and also the lead terminal over the gate electrode 3 may be made of copper similar to one over the emitter electrode 2.

As above, the direct-lead-bonding technique can be used for connection of the gate electrode 3 so that the resistance of the wiring to the gate electrode 3 can be reduced.

Also, it should be noted that the gate wiring based upon the direct-lead-bonding technique can be used in the semiconductor devices 100, 200 as well.

### Embodiment 4

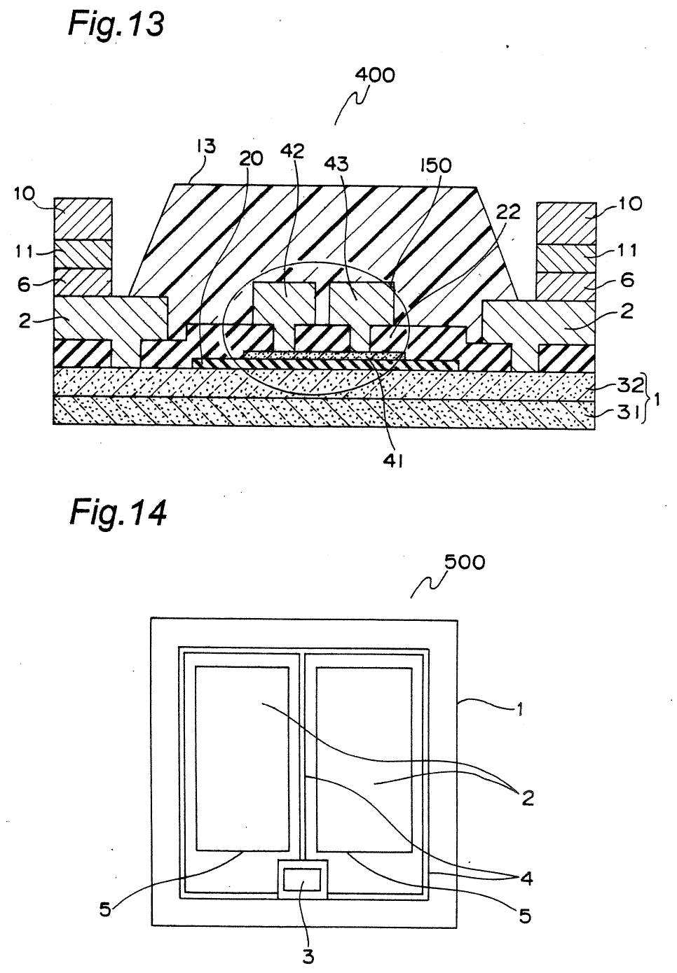

FIG. 12 is a top plan view of a fourth embodiment of a semiconductor device according to the present invention, which is entirely denoted by reference numeral 400. FIG. 13 is a cross sectional view taken along a XII-XII line of FIG. 12. Reference numerals in FIGS. 12 and 13 similar to those in FIGS. 1 and 2 denote the same or similar components.

According to the fourth embodiment, the polyimide layer 13 is adapted to cover optional elements (functional elements) rather than the gate wiring of the semiconductor device. The semiconductor device 400 includes a temperature sensing element 150 as the optional or functional element in addition to the gate wiring (not shown).

As illustrated in FIG. 12, the semiconductor device 400 includes the temperature sensing element 150 between the emitter electrodes 2. Also, as shown in FIG. 13, the temperature sensing element 150 includes a diode 41 of polycrystalline silicon, a cathode electrode 42 connected with the cathode of the diode 41, and a anode electrode connected with the anode of the diode 41.

The cathode electrode 42 and the anode electrode 43 are connected via the wirings 151 with the terminals 152. To this result, the resistance of the diode 41 varying in accordance with the temperature is measured with reading across the terminals 152 to detect the temperature of the semiconductor chip.

According to the semiconductor device 400 of the fourth embodiment of FIG. 13, the polyimide layer 13 is formed to cover the temperature sensing element 150, and has thickness of about 10 μm through 50 μm.

Therefore, even if the metal layer 6 is formed offset towards the temperature sensing element 150 from the emitter electrode 2, since the polyimide layer 13 performs a function serving as a buffer layer for reducing mechanical stress while bonding the lead terminal plate 10 via the solder layer 11 onto the metal layer 6, the temperature sensing element 150 can be prevented from being damaged.

The optional (functional) element may include a current-sensing element rather than the temperature sensing element 150.

### Embodiment 5

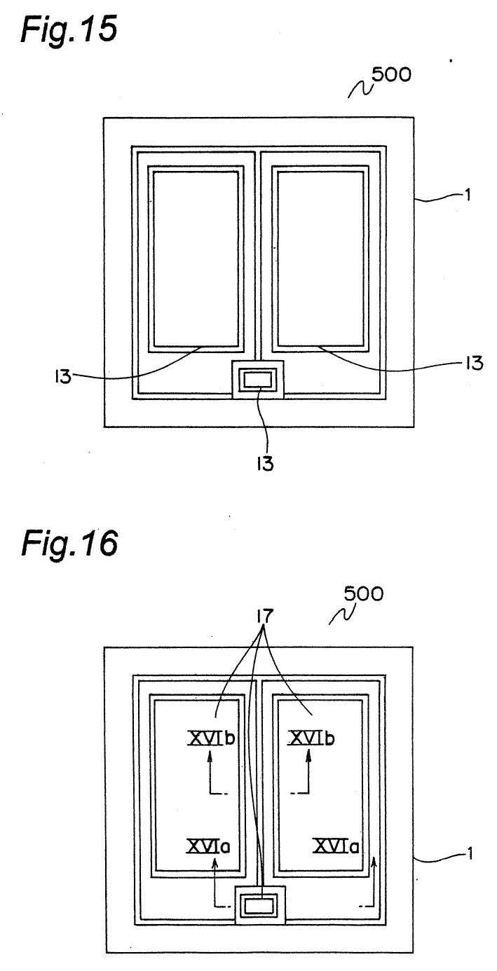

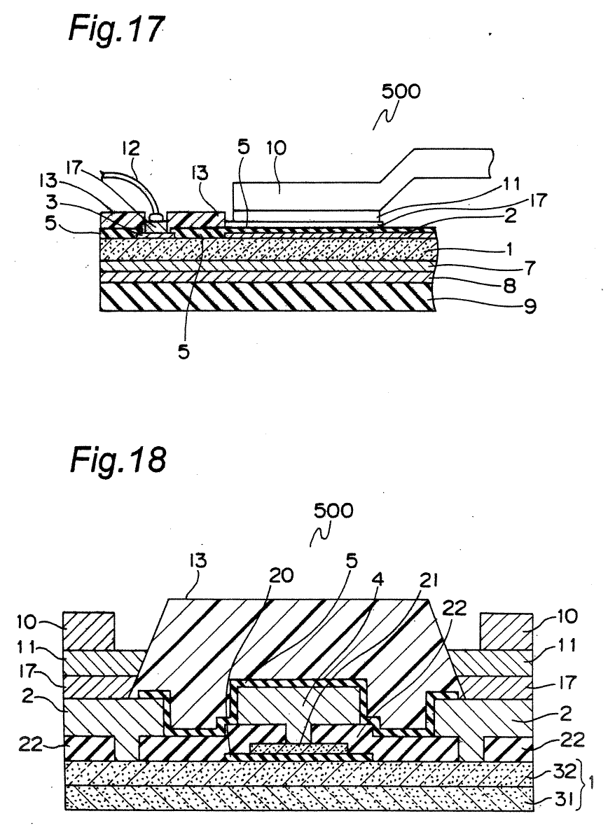

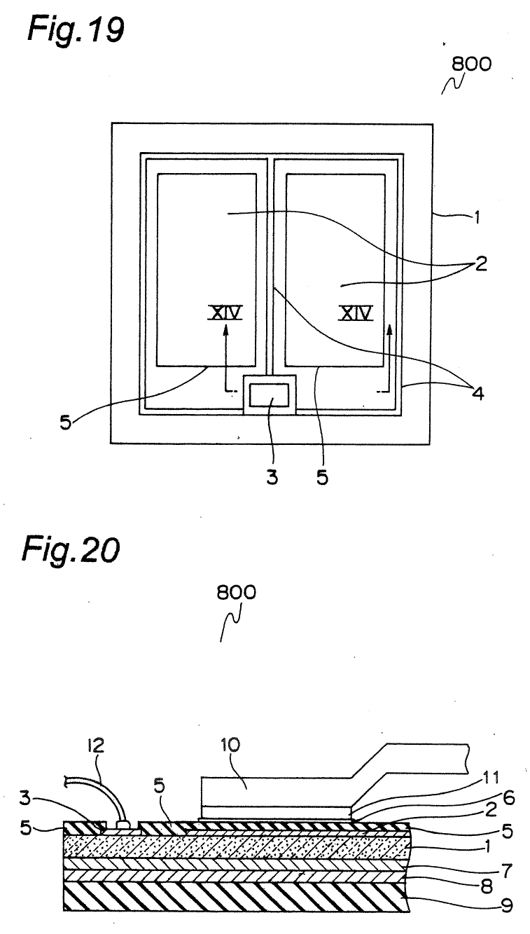

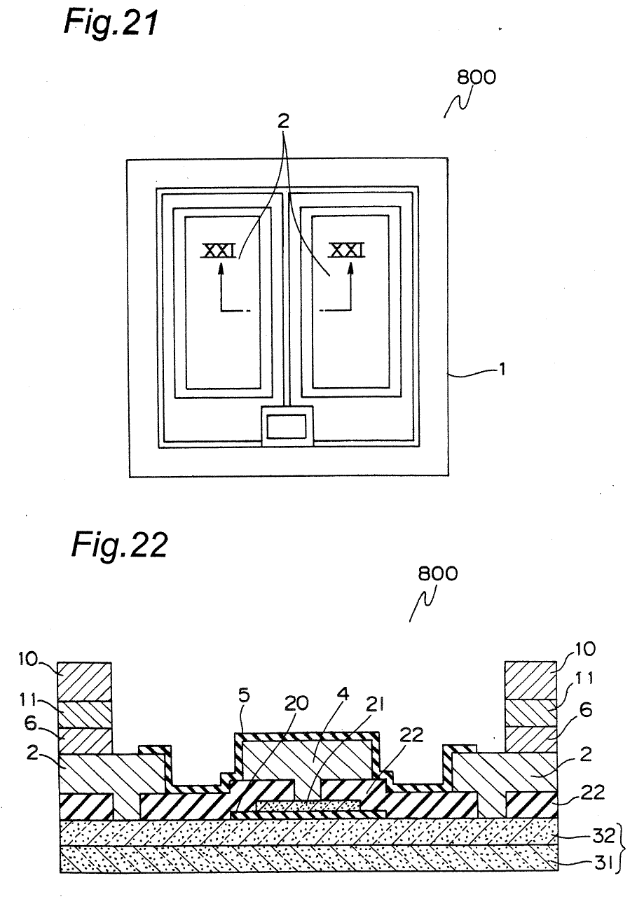

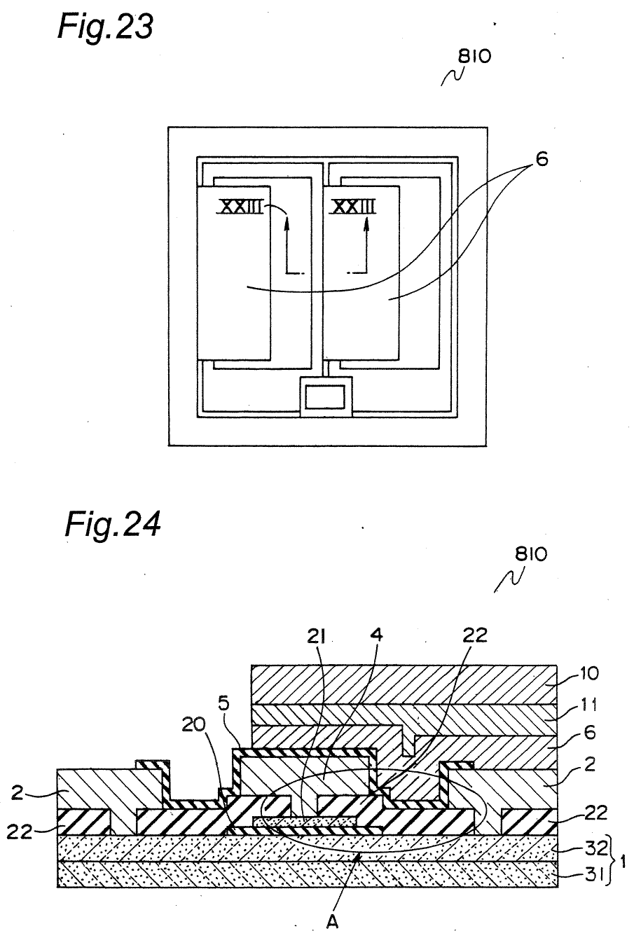

FIGS. 14-16 are top plan views of a fifth embodiment of a semiconductor device according to the present invention, which is entirely denoted by reference numeral 500. FIGS. 17 and 18 are cross sectional views taken along a XVIa-XVIa line and a XVIb-XVIb line of FIG. 16, respectively. Reference numerals in FIGS. 14-18 similar to those in FIGS. 1 and 2 denote the same or similar components.

According to the semiconductor device 500 shown in FIGS. 14-16, after forming the emitter electrode 2, a polyimide layer 13 is formed entirely on the semiconductor chip 1 except the central regions of the emitter electrode 2 and the gate electrode 3. Such formation of the polyimide layer 13 can be achieved by a typical photolithograph technique. Then, as shown in FIG. 16, a plating technique is used for forming a metal layer 17 on the central regions on the emitter electrode 2 and the gate electrode 3 where the polyimide layer 13 is not covered.

As above, plating on the exposed region of the emitter electrode 2 that are not covered by the polyimide layer 13 causes the selective formation of the metal layer 17. This eliminates the necessity of precise alignment of the metal mask relative to the wafer when forming the metal layer 17, and avoids misalignment of the mask. Also, this allows the metal layer to be formed simultaneously both on the emitter electrode 2 and the gate electrode 3.

Further, according to the semiconductor device 500 of the present embodiment shown in FIG. 18, since the metal layer 17 is formed by plating, the metal layer 17 and the solder layer 11 are formed to contact with the side wall (shoulder portion) of the polyimide layer 13. Also in this case, the polyimide layer 13 performs the function serving as a buffer layer thereby to prevent the damage of the gate wiring 4.

As described above for the first through fifth embodiments, while the IGBT is used as the semiconductor chip, the present invention can be adapted to any other power MOSFETs. When a lateral power MOSFET is used, the electrodes on both sides of the gate wiring are the source/drain electrodes.

Furthermore, the present invention can be adapted to any other diodes and CSTBT (Carrier Stored Trench Gate Bipolar Transistor) commercially available from Mitsubishi Denki Kabushiki Kaisha, Tokyo, Japan. Moreover, it can also be adapted to the device rather than the power semiconductor devices, such as the HVIC (High Voltage IC) and LSI.

What is claimed is:

1. A semiconductor device, comprising:
a semiconductor substrate;
a surface electrode on said semiconductor substrate;
a gate wiring on said semiconductor substrate, said gate wiring being spaced from said surface electrode;
a metal layer on said surface electrode;
a lead terminal plate connected onto said metal layer; and
a polyimide layer covering said gate wiring.

2. The semiconductor device according to claim 1, wherein said metal layer and said lead terminal plate are provided over said gate wiring.

3. The semiconductor device according to claim 1, further comprising a functional element on said semiconductor substrate, which is spaced from said surface electrode and covered by said polyimide layer.

4. The semiconductor device according to claim 1, further comprising an overcoat layer intervened between said gate wiring and said polyimide layer.

5. The semiconductor device according to claim 1, wherein said polyimide layer has thickness in the range between about 10 μm and about 50 μm.

6. The semiconductor device according to claim 1, further comprising:
a gate electrode on said semiconductor substrate, which is connected with said gate wiring; and
a gate metal layer formed on said gate electrode; and
a gate lead terminal plate connected onto said gate metal layer.

7. The semiconductor device according to claim 1, wherein said metal layer is formed by a group consisting of a deposition technique, a sputtering technique, and a plating technique.

8. The semiconductor device according to claim 1, further comprising a reverse electrode opposing to said surface electrode, wherein current running between the surface electrode and reverse electrode is controlled by a voltage applied to said gate wiring.
